(19) United States
(12) Patent Application Publication
(10) Pub. No.: US 2025/0308576 A1
(43) Pub. Date: Oct. 2, 2025

(54) SEMICONDUCTOR MEMORY DEVICE AND CONTROL METHOD THEREOF

(71) Applicant: Winbond Electronics Corp., Taichung City (TW)

(72) Inventor: Taihei SHIDO, Yokohama (JP)

(73) Assignee: Winbond Electronics Corp., Taichung City (TW)

(21) Appl. No.: 19/093,745

(22) Filed: Mar. 28, 2025

(30) Foreign Application Priority Data
Apr. 1, 2024 (JP) 2024-059011

(51) Int. Cl. G11C 11/4091

(52) U.S. Cl. CPC G11C 11/4091

(57) ABSTRACT

The semiconductor memory device includes multiple memory banks (20), a first voltage supply unit (30), and a control unit (40). Each of the memory banks (20) includes at least one sense amplifier (10). When amplifying the voltage of the bit lines (BLT, BLC) connected to the sense amplifiers (10) of the memory banks (20), the first voltage supply unit (30) supplies an overdrive voltage (VOD) that is higher than the operating voltage (VBLH) of the sense amplifier (10) to the sense amplifiers (10) of each of the memory banks (20). The control unit (40) controls the supply of a charging voltage for the overdrive voltage (VOD) in such a way that the overdrive voltage is supplied to the sense amplifier (10) of any one of the memory banks (20) without a voltage drop when any one of the multiple memory banks (20) is performing the amplification operation.

### CROSS REFERENCE TO RELATED APPLICATIONS

This Application claims priority of Japanese Patent Application No. 2024-059011, filed on Apr. 1, 2024, the entirety of which is incorporated by reference herein.

### BACKGROUND OF THE INVENTION

### Field of the Invention

The present invention relates to a semiconductor memory device and its control method.

### Description of the Related Art

Dynamic Random Access Memory (DRAM) generates a small voltage difference on a pair of complementary bit lines (hereinafter referred to as “a pair of bit lines”) based on the data stored in the memory banks, and then amplifies this voltage difference through a sense amplifier to read the data. In order to speed up the voltage amplification operation of the bit lines, the semiconductor memory device accelerates the data readout operation of the sense amplifier by supplying an overdrive voltage to the sense amplifier at the beginning of the amplification operation, wherein the overdrive voltage is higher than the voltage of the sense amplifier.

### BRIEF SUMMARY OF THE INVENTION

As shown in FIG. 1(A), the overdrive voltage (VOD) supply unit that supplies the VOD is shared between multiple memory banks (memory bank 0, memory bank 1) that include multiple memory banks and multiple sense amplifiers (in the example of the diagram, there are two). When performing the voltage amplification of the bit lines connected to the sense amplifiers in each of the multiple memory banks (memory bank 0, memory bank 1), the VOD supply unit supplies the overdrive voltage to the sense amplifiers of each memory bank.

FIG. 1(B) shows an example of the voltage changes of the signal for each sense amplifier in multiple memory banks (memory bank 0, memory bank 1). In the example of FIG. 1(B), at time t1, the data stored in any memory bank within memory bank 0 (BK0) is transferred to the bit line BLT (BK0), causing a slight change in the voltage level of bit line BLT (BK0). When the voltage amplification of the bit line starts at time t2, the voltage levels of the pair of bit lines BLT (BK0) and BLC (BK0) are amplified by the sense amplifier connected to this pair of bit lines. At this point, the overdrive voltage is supplied to the sense amplifier of Memory bank 0 (BK0) from the VOD supply unit, causing the voltage at the node VOD_BK01 between the VOD supply unit and each memory bank (memory bank 0, memory bank 1) to decrease.

At time t3, when the voltage levels of the pair of bit lines BLT (BK0) and BLC (BK0) in memory bank 0 (BK0) are amplified to the same voltage as the operating voltage VBLH and the ground voltage VSS, the VOD supply unit stops supplying the overdrive voltage to the sense amplifier of memory bank 0 (BK0). At this point, the voltage at node VOD_BK01 begins to rise to restore to the initial state (the state where the voltage has not decreased).

At time t4, when the voltage at node VOD_BK01 has not yet returned to its initial state and the voltage amplification operation of the bit lines BLT (BK1) and BLC (BK1) in memory bank 1 (BK1) begins, the voltage at node VOD_BK01 (i.e., the overdrive voltage) will decrease further compared to the voltage at time t2, due to the overdrive voltage being supplied to the sense amplifier of memory bank 1 (BK1) from the VOD supply unit. As a result, the voltage of bit line BLT (BK1) will be amplified with a lower overdrive voltage. In this case, the time for the voltage of bit line BLT (BK1) to reach the operating voltage VBLH is extended (i.e., the amplification operation becomes longer), causing the data readout operation of the sense amplifier in memory bank 1 to slow down. Therefore, when the overdrive voltage is shared between multiple memory banks (memory bank 0, memory bank 1), it becomes difficult to enable the sense amplifiers of each memory bank (in this case, memory bank 1) to operate at high speed.

The present invention provides a semiconductor memory device comprising multiple memory banks, a first voltage supply unit, and a control unit. Each of the memory banks includes at least one sense amplifier. The first voltage supply unit supplies an overdrive voltage (which is higher than the operating voltage of the sense amplifier) to the sense amplifiers of the multiple memory banks during the voltage amplification operation of the bit lines connected to each sense amplifier in the multiple memory banks. In order to charge the overdrive voltage, the overdrive voltage is supplied to the sense amplifier of the memory bank without any voltage drop when any of the memory banks performs the amplification operation.

In the case where any memory bank performs the amplification operation, the overdrive voltage, which has not yet dropped, can still be supplied to the sense amplifier of the memory bank. For example, compared to the case where the overdrive voltage in a voltage drop state is supplied to the sense amplifier of any memory bank, this allows the amplification operation of the memory bank to be sped up, thereby accelerating the operation of the sense amplifier of the memory bank. Even when the overdrive voltage is shared between multiple memory banks, the sense amplifiers of each memory bank can still operate at high speed.

The present invention provides a control method for a semiconductor memory device, wherein the semiconductor memory device comprises multiple memory banks, a first voltage supply unit, and a control unit. Each of the memory banks includes at least one sense amplifier. The first voltage supply unit supplies an overdrive voltage (which is higher than the operating voltage of the sense amplifier) to the sense amplifiers of the multiple memory banks during the voltage amplification operation of the bit lines connected to each sense amplifier in the multiple memory banks. The control unit performs the following steps. In order to charge the overdrive voltage, the overdrive voltage is supplied to the sense amplifier of the memory bank without any voltage drop when any of the memory banks performs an amplification operation.

According to the semiconductor memory device and its control method of the present invention, even when the overdrive voltage is shared between multiple memory banks, the sense amplifiers of each memory bank can still operate at high speed.

### BRIEF DESCRIPTION OF THE DRAWINGS

The present invention can be more fully understood by reading the subsequent detailed description and examples with references made to the accompanying drawings, wherein:

FIG. 1(A) shows a partial block diagram of a semiconductor memory device in the prior art;

FIG. 1(B) shows a diagram of voltage variations of signals for each sense amplifier in a plurality of memory banks in the prior art;

FIGS. 2(A) and 2(B) show the configuration of a semiconductor memory device in an embodiment of the present invention;

FIGS. 3 and 4 show the voltage variations of signals for each sense amplifier in a plurality of memory banks in different embodiments of the present invention;

FIGS. 5 and 6 show the configuration of a semiconductor memory device in an embodiment of the present invention.

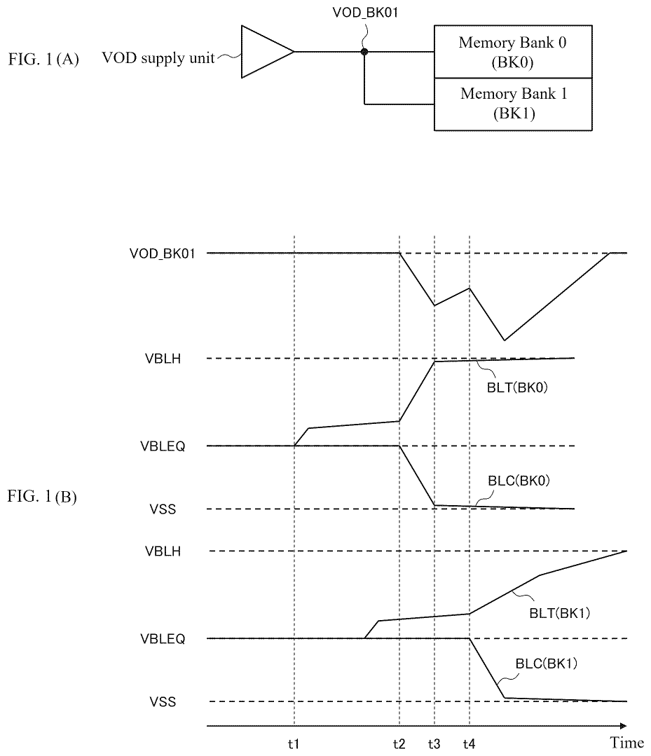

### DETAILED DESCRIPTION OF THE INVENTION

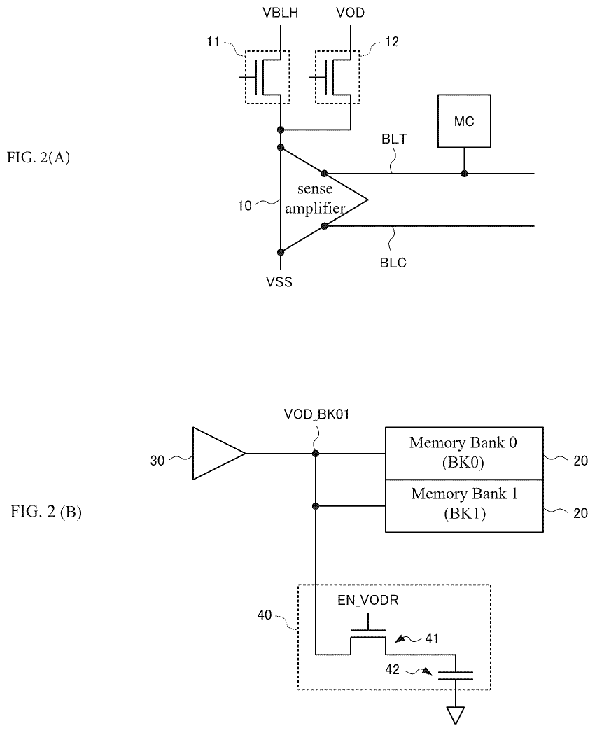

As shown in FIG. 2(A), the semiconductor memory device includes multiple sense amplifiers 10 connected to multiple memory banks MC. In order to avoid making the diagram unclear, only one memory bank MC and one sense amplifier 10 are shown. Additionally, the memory banks MC and sense amplifiers 10 may have the same configuration as those in known technologies.

As shown in FIG. 2(A), the sense amplifier 10 is connected to a pair of bit lines, BLT and BLC, with the memory bank MC connected to bit line BLT. The node on the high voltage power side of the sense amplifier 10 is connected to the operating voltage VBLH through switch 11, and to the overdrive voltage VOD through switch 12. Furthermore, the node on the high voltage power side of the sense amplifier 10 is controlled by a control unit 40, which controls the switching on and off of switches 11 and 12, thereby connecting the node to either the operating voltage VBLH or the overdrive voltage VOD. The node on the low voltage power side of the sense amplifier 10 is connected to the ground voltage VSS. Additionally, in FIG. 2(A), switches 11 and 12 are shown as being constructed from N-channel MOSFETs (nMOSFETs), but other circuits or components could also be used to construct switches 11 and 12.

Additionally, the semiconductor memory device according to the embodiment of the present invention, as shown in FIG. 2(B), includes: multiple memory banks 20 (two in the diagram), a first voltage supply unit 30, and a control unit 40. Each of the multiple memory banks 20 includes: at least one memory bank MC and at least one sense amplifier 10. The multiple memory banks 20 are configured to include at least one of the structures shown in FIG. 2(A). The first voltage supply unit 30 is connected to the multiple memory banks 20 through node VOD_BK01. During the voltage amplification operation of the bit lines BLT and BLC connected to the sense amplifiers 10 of the multiple memory banks 20, the overdrive voltage VOD, which is higher than the operating voltage VBLH of the sense amplifiers 10, is supplied to the sense amplifiers 10 of the multiple memory banks 20. Furthermore, the first voltage supply unit 30 may also be configured to generate the overdrive voltage VOD based on a power supply provided externally.

The control unit 40, when any of the memory banks 20 in the multiple memory banks 20 performs an amplification operation, supplies the overdrive voltage VOD to the sense amplifier 10 of the memory bank 20 without any voltage drop, in order to charge the overdrive voltage VOD.

Additionally, the control unit 40, when any of the memory banks 20 in the multiple memory banks 20 begins the amplification operation, stops the supply of the charging voltage. Thus, when any memory bank 20 starts the amplification operation (i.e., when the overdrive voltage VOD is supplied to the sense amplifier 10 of the memory bank 20), the charging voltage is suppressed.

The control unit 40, during the amplification operation, starts the supply of the charging voltage when the voltage of bit line BLT reaches the same voltage as the operating voltage VBLH of the sense amplifier 10. The term “same voltage” is not limited to the condition where the voltage of bit line BLT is exactly equal to the operating voltage VBLH; for example, it may also include cases where the voltage difference between bit line BLT and operating voltage VBLH is sufficiently small, such that the two voltages can be considered equivalent. Thus, when the voltage of bit line BLT reaches the same voltage as the operating voltage VBLH of the sense amplifier 10 (i.e., when the supply of overdrive voltage VOD to the sense amplifier 10 of any memory bank 20 is stopped), the charging voltage can be supplied to recharge the reduced overdrive voltage VOD.

The control unit 40, after an amplification operation is performed on any memory bank 20 and before another memory bank 20 (other than the one performing the amplification) begins its amplification operation, supplies the charging voltage to restore the overdrive voltage VOD to a state without a voltage drop during the period before the amplification operation of the other memory bank 20 starts. The term “overdrive voltage VOD without the voltage drop” is not limited to a condition wherein the overdrive voltage VOD experiences absolutely no voltage drop; for example, it also includes situations where the voltage value of the overdrive voltage VOD is only slightly reduced, but can still be considered as being in the same state as if there were no voltage drop. Thus, when the amplification operation of the other memory bank 20 begins, the overdrive voltage VOD without the voltage drop can be supplied to the sense amplifier 10 of the other memory bank 20.

As shown in FIG. 2(B), the control unit 40 includes: a switch 41 for controlling the supply of the charging voltage; and a circuit (here, a capacitor 42) for charging the overdrive voltage VOD. The switch 41 is placed between node VOD_BK01 and the capacitor 42. Additionally, the switch 41 includes an nMOSFET, such that when a high-level signal EN_VODR is input to the gate terminal of the nMOSFET, the capacitor 42 is connected to node VOD_BK01 (i.e., the charging voltage is supplied to charge the capacitor 42). The capacitance value of capacitor 42 can also be set in such a way that the charging voltage supplied to the capacitor 42 becomes a higher voltage than the overdrive voltage VOD. Additionally, in this embodiment, although the switch 41 is described as including an nMOSFET, switch 41 may also include, for example, a p-channel MOSFET (pMOSFET), or other types of switching circuits such as circuits other than MOSFETs. Furthermore, while the circuit for charging the overdrive voltage VOD is described as including capacitor 42, this circuit may also have other configurations.

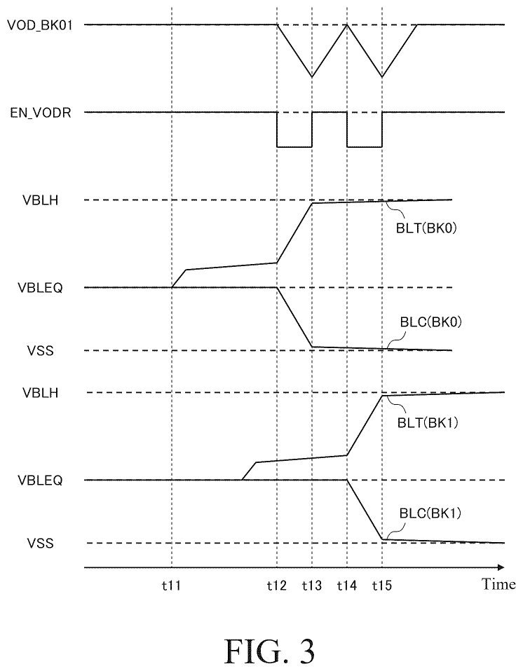

Referring to FIG. 3, the operation of the control unit 40 when the sense amplifiers 10 of the multiple memory banks 20 are in operation is explained. Additionally, the process of reading the data stored in the memory banks MC of each memory bank 20 will be described.

First, in the standby state, the voltage of the pairs of bit lines BLT(BK0), BLC(BK0), BLT(BK1), and BLC(BK1) connected to the sense amplifiers 10 of each memory bank (memory bank 0, memory bank 1) 20 is set to the equalizer voltage VBLEQ. Here, the level of the equalizer voltage VBLEQ is set to half of the operating voltage VBLH.

At time t11, the data stored in any memory bank MC within memory bank 0 (BK0) is transferred to the bit line BLT(BK0) connected to the memory bank MC, causing a slight change in the voltage level of the bit line BLT(BK0). Additionally, between time t11 and time t12, the data stored in any memory bank MC within memory bank 1 (BK1) is transferred to the bit line BLT(BK1) connected to this memory bank MC, causing a slight change in the voltage level of the bit line BLT(BK1).

Next, at time t12, when the voltage amplification operation of the bit line in memory bank 0 (BK0) begins, the control unit 40 stops supplying charging voltage to the capacitor 42 for overdrive voltage VOD. Specifically, the control unit 40 turns off switch 41 by applying a low-level signal EN_VODR to the gate terminal of the nMOSFET in switch 41. This blocks the connection between capacitor 42 and node VOD_BK01, halting the charging of the overdrive voltage VOD. Additionally, the control unit 40 turns on switch 12, which is connected to the sensing amplifier 10 performing the bit line voltage amplification operation (i.e., applying a high-level signal to the gate terminal of the nMOSFET in switch 12). As a result, the first voltage supply unit 30 supplies overdrive voltage VOD to the sensing amplifier 10.

Next, at time t13, when the voltage levels of the bit lines BLT(BK0) and BLC(BK0) in memory bank 0 (BK0) are amplified to the same voltage as the operating voltage VBLH and ground voltage VSS, the control unit 40 begins supplying charging voltage. Additionally, the time at which the voltage levels of the bit lines BLT(BK0) and BLC(BK0) are amplified to the same voltage as the operating voltage VBLH and ground voltage VSS can be determined through prior measurement, or it can be detected by a specific voltage detection circuit (omitted in the diagram) that monitors when the voltage levels of the bit lines BLT(BK0) and BLC(BK0) reach the same voltage as the operating voltage VBLH and ground voltage VSS.

Here, the control unit 40 inputs a high-level signal EN_VODR to the gate terminal of the nMOSFET of switch 41, thereby turning on switch 41. This connects the capacitor 42 to node VOD_BK01, starting the charging of the overdrive voltage VOD. Additionally, the control unit 40 turns off switch 12, which is connected to the sensing amplifier 10 performing the bit line voltage amplification (i.e., inputs a low-level signal to the gate terminal of the nMOSFET of switch 12). This causes switch 11, connected to the sensing amplifier 10, to turn on (i.e., inputs a high-level signal to the gate terminal of the nMOSFET of switch 11). As a result, the supply of the overdrive voltage VOD to the sensing amplifier 10 from the first voltage supply unit 30 is stopped, and the operating voltage VBLH is supplied to the sensing amplifier 10. Furthermore, the voltage at node VOD_BK01 (overdrive voltage VOD) rises as it is charged by the charging voltage.

Next, the control unit 40 stops supplying the charging voltage to the overdrive voltage VOD when the voltage at node VOD_BK01 (overdrive voltage VOD) returns to its initial state (the state without voltage drop). The time point when the voltage at node VOD_BK01 returns to its initial state can be determined by prior measurement or can be detected by a specific voltage detection circuit (which is omitted in the diagram) that detects when the voltage at node VOD_BK01 returns to its initial state. In this way, after the amplification operation in memory bank 0 (BK0) and during the amplification operation in memory bank 1 (BK1), the overdrive voltage VOD is restored to a state without a voltage drop before the start of the amplification operation in memory bank 1 (BK1), and the charging voltage is supplied.

Then, at time t14, when the voltage amplification operation of the bit lines in memory bank 1 (BK1) begins, the control unit 40 stops supplying the charging voltage to capacitor 42 in the same manner as the operation at time t12. Additionally, the control unit 40 supplies the overdrive voltage VOD to the sensor amplifier 10 of memory bank 1 (BK1) through the first voltage supply unit 30. At this time, the overdrive voltage VOD has already returned to its initial state (the state without voltage drop), so when the sensor amplifier 10 in memory bank 1 (BK1) performs the amplification operation, the overdrive voltage VOD is supplied to the sensor amplifier 10 of memory bank 1 (BK1) without any voltage drop.

Additionally, in the example shown in FIG. 3, it is illustrated that the point in time when the voltage at node VOD_BK01 (overdrive voltage VOD) returns to its initial state (the state without voltage drop) coincides with the point in time when the voltage amplification operation of the bit lines in memory bank 1 (BK1) begins. Here, the control unit 40 may control in the following way: it keeps the voltage amplification operation of the bit lines in memory bank 1 (BK1) in standby until the voltage at node VOD_BK01 (overdrive voltage VOD) recovers to its initial state (the state without voltage drop), and then does it start the voltage amplification operation of the bit lines in memory bank 1 (BK1). This ensures that the overdrive voltage VOD is reliably supplied to the sensor amplifier 10 of memory bank 1 (BK1) without any voltage drop.

At time t15, when the voltage levels of the bit lines BLT(BK1) and BLC(BK1) in memory bank 1 (BK1) are amplified to the same voltage as the operating voltage VBLH and the ground voltage VSS, the control unit 40 starts supplying the charging voltage in the same operation as at time t13.

In this way, when an amplification operation is performed in any memory bank 20, the overdrive voltage VOD without a voltage drop can be supplied to the sense amplifier 10 of that memory bank 20.

According to the semiconductor memory device and its control method of this embodiment, when an amplification operation is performed in any memory bank 20, the overdrive voltage VOD without a voltage drop can be supplied to the sense amplifier 10 of that memory bank 20. In comparison to supplying a voltage-reduced overdrive voltage VOD to the sense amplifier 10 of that memory bank 20, the amplification operation of this memory bank 20 can be sped up, thereby enabling faster operation of the sense amplifier 10 of this memory bank 20. As a result, even when the overdrive voltage VOD is shared among multiple memory banks 20, the sense amplifiers 10 of each memory bank 20 can still operate at high speed.

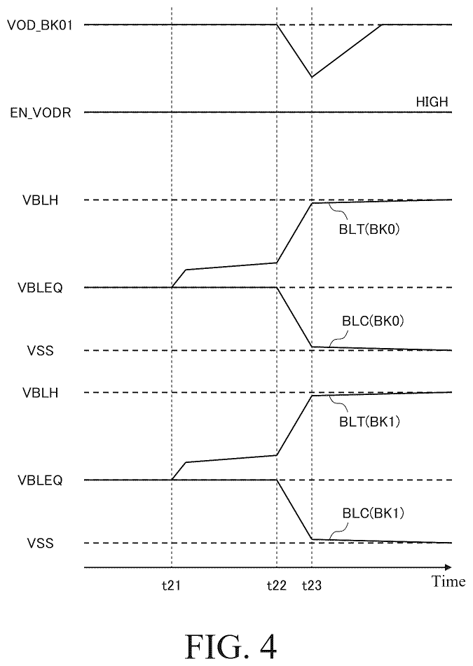

In the above embodiment, it was explained with the example where the voltage amplification operation of the bit line of memory bank 1 (BK1) starts only after the voltage amplification operation of the bit line of memory bank 0 (BK0) begins. However, the present invention is not limited to this situation. For example, as shown in FIG. 4, the voltage amplification operations of the bit lines of multiple memory banks 20 (memory bank 0, memory bank 1) can be performed simultaneously. In this case, the control unit 40 can be configured to continuously supply the charging voltage (i.e., the signal EN_VODR is continuously set to a high level) when the amplification operations of at least two memory banks 20 are performed simultaneously. As a result, since the charging voltage is continuously supplied to the overdrive voltage VOD, the reduction in the overdrive voltage VOD caused by the simultaneous voltage amplification operations of the bit lines of multiple memory banks 20 (memory bank 0, memory bank 1) can be minimized.

Additionally, in FIG. 4, the operation of the control unit 40 may also be such that, except for the times t21, t22, and t23 where the voltage amplification operations of the bit lines of multiple memory banks 20 (memory bank 0, memory bank 1) are performed simultaneously and the signal EN_VODR is continuously set to a high level, the other operations are the same as those at times t11, t12, and t13 as described above.

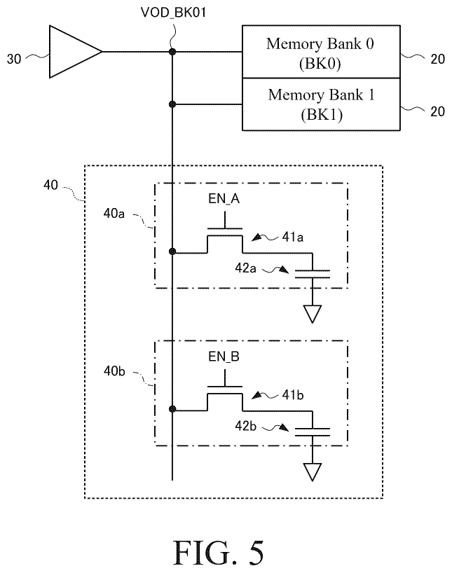

Additionally, in the above embodiment, although the control unit 40 was described as including a switch 41 and a capacitor 42, the present invention is not limited to this configuration. For example, as shown in FIG. 5, the control unit 40 may include several control units, the number of which corresponds to the number of memory banks 20 (in the example of the figure, the first control unit 40a and the second control unit 40b). The first control unit 40a and the second control unit 40b each include a switch 41a, 41b and a capacitor 42a, 42b. In this case, the first control unit 40a and the second control unit 40b may each correspond to a specific memory bank 20 among multiple memory banks 20. For example, the first control unit 40a may correspond to memory bank 0 (BK0), and the second control unit 40b may correspond to memory bank 1 (BK1).

Additionally, the charging voltage applied to each capacitor 42a, 42b may differ from one another. This allows for different charging voltages to be associated with each of the multiple memory banks 20. Since the reduction in the overdrive voltage VOD during the amplification operation of any given memory bank 20 increases as the position of that memory bank 20 becomes farther from the first voltage supply unit 30, the charging voltage applied to each capacitor 42a, 42b can be set to increase as the corresponding memory bank 20 is positioned farther from the first voltage supply unit 30.

The control unit 40: In the case where any memory bank 20 among multiple memory banks 20 performs an amplification operation, it supplies the charging voltage corresponding to that memory bank 20. This allows the charging voltage corresponding to the memory bank 20 performing the amplification operation to be charged to the overdrive voltage VOD. Additionally, the first control unit 40a of the control unit 40 may, in the case where the amplification operation is being performed by memory bank 0 (BK0), input a high-level signal EN_A to the gate terminal of the nMOSFET in switch 41a, thereby supplying the charging voltage for capacitor 42a to the overdrive voltage VOD. Additionally, the first control unit 40a of the control unit 40, when the overdrive voltage VOD has returned to a state with no voltage drop, inputs a low-level signal EN_A to the gate terminal of the nMOSFET in switch 41a, thereby stopping the supply of charging voltage. Furthermore, the second control unit 40b of the control unit 40, when memory bank 1 (BK1) performs an amplification operation, inputs a high-level signal EN_B to the gate terminal of the nMOSFET in switch 41b, thereby supplying the charging voltage for capacitor 42b to the overdrive voltage VOD. Additionally, the second control unit 40b of the control unit 40, when the overdrive voltage VOD has returned to a state with no voltage drop, inputs a low-level signal EN_B to the gate terminal of the nMOSFET in switch 41b, thereby stopping the supply of charging voltage.

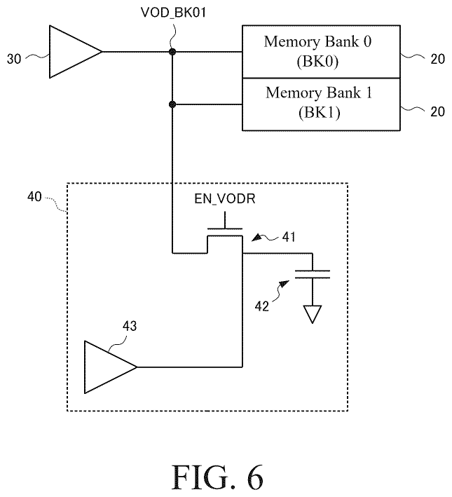

FIG. 6 shows an example of the configuration of the control unit 40 according to another embodiment of the present invention. As shown in FIG. 6, the control unit 40 may also include a second voltage supply unit 43. In this case, the second voltage supply unit 43 can supply multiple different charging voltages to the capacitor 42. It is also possible that each of the different charging voltages is associated with a corresponding memory bank 20 from the multiple memory banks 20, as shown in the embodiment of FIG. 5. For example, the charging voltage supplied to the capacitor 42 can be set to increase as the distance between the corresponding memory bank 20 and the first voltage supply unit 30 increases.

In this embodiment, the control unit 40 supplies one of the multiple charging voltages to the overdrive voltage VOD. As a result, different charging voltages can be used to charge the overdrive voltage VOD. For example, the control unit 40 can supply the charging voltage corresponding to memory bank 0 (BK0) from the second voltage supply unit 43 to the capacitor 42 when the amplification operation is performed in memory bank 0 (BK0), and supply the charging voltage corresponding to memory bank 1 (BK1) from the second voltage supply unit 43 to the capacitor 42 when the amplification operation is performed in memory bank 1 (BK1).

In the above embodiment, the control unit 40 is described as including at least one switch (41, 41a, 41b) and at least one capacitor (42, 42a, 42b) as an example. However, the present invention is not limited to this configuration. For example, the control unit 40 may also be constructed using other circuits that achieve the same effects and functions as those described in the above embodiment.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor memory device, comprising:
a plurality of memory banks, each of which includes at least one sense amplifier;
a first voltage supply unit, supplying an overdrive voltage that is higher than an operating voltage of the sense amplifier to each sense amplifier of the plurality of memory banks when a bit line voltage connected to each of the sense amplifiers in the plurality of memory banks is amplified; and
a control unit, supplying the overdrive voltage without a voltage drop to serve as a charging voltage and providing the charging voltage to the sense amplifier of any memory bank to charge the overdrive voltage, when any memory bank of the plurality of memory banks performs the amplification operation.

2. The semiconductor memory device as claimed in claim 1, wherein the control unit stops supplying the charging voltage when any memory bank of the plurality of memory banks begins the amplification operation.

3. The semiconductor memory device as claimed in claim 1, wherein the control unit supplies the charging voltage when the voltage of the bit line reaches the operating voltage of the sense amplifier during the amplification operation.

4. The semiconductor memory device as claimed in claim 1, wherein after the amplification operation is performed in any memory bank and before the amplification operation in another memory bank other than the any memory bank is performed, the control unit restores the overdrive voltage to a state without the voltage drop during a period prior to a start of the amplification operation in the another memory bank and supplies the charging voltage.

5. The semiconductor memory device as claimed in claim 1, wherein the control unit continuously supplies the charging voltage when the amplification operation of at least two memory banks among the plurality of memory banks is performed simultaneously.

6. The semiconductor memory device as claimed in claim 1, wherein the control unit includes a circuit for charging the overdrive voltage.

7. The semiconductor memory device as claimed in claim 6, wherein the circuit includes a capacitor for charging the overdrive voltage.

8. The semiconductor memory device as claimed in claim 1, wherein the control unit includes a switch that is configured to control supplying the charging voltage.

9. The semiconductor memory device as claimed in claim 8, wherein the switch comprises a MOS transistor.

10. The semiconductor memory device as claimed in claim 1, wherein each of the multiple memory banks corresponds to a different charging voltage;
wherein the control unit supplies the charging voltage corresponding to the any memory bank when the amplification operation is performed in the any memory bank of the plurality of memory banks.

11. The semiconductor memory device as claimed in claim 1, wherein the control unit supplies any one of the plurality of charging voltages.

12. The semiconductor memory device as claimed in claim 11, wherein the control unit includes a second voltage supply unit that supplies the plurality of charging voltages.

13. A control method for a semiconductor memory device, the semiconductor memory device comprising:
a plurality of memory banks, including at least one sense amplifier;
a first voltage supply unit, supplying an overdrive voltage that is higher than an operating voltage of the sense amplifier to each sense amplifier of the plurality of memory banks, when a bit line voltage connected to each sense amplifier in the unit is amplified; and
a control unit;
wherein the control method comprising:
supplying the overdrive voltage without a voltage drop to serve as a charging voltage and providing the charging voltage to the sense amplifier of any memory bank to charge the overdrive voltage, when the any memory bank of the plurality of memory banks performs an amplification operation.

14. The control method as claimed in claim 13, wherein the control method further comprising:
stop supplying the charging voltage when the any memory bank in the plurality of memory banks begins the amplification operation.

15. The control method as claimed in claim 13, wherein the control method further comprising:
supplying the charging voltage when the voltage of the bit line reaches the operating voltage of the sense amplifier during the amplification.

16. The control method as claimed in claim 13, wherein the control method further comprising:
supplying the charging voltage, during a period prior to a start of the amplification operation in another memory bank other than the any memory bank, after the amplification operation is performed in the any memory bank and before the amplification operation in the another memory bank is performed to restore the overdrive voltage to a state without the voltage drop by the control unit.

17. The control method as claimed in claim 13, wherein the control method further comprising:
supplying the charging voltage continuously when the amplification operation in at least two of the plurality of memory banks is performed simultaneously.

18. The control method as claimed in claim 13, wherein each of the plurality of memory banks corresponds to a different charging voltage, wherein the control method further comprising:
supplying the charging voltage corresponding to the any memory bank when the amplification operation is performed in the any memory bank in the plurality of memory banks.
